(19) United States
(12) Patent Application Publication
(10) Pub. No.: US 2026/0305443 A1
(43) Pub. Date: Oct. 1, 2026

(54) DIE ATTACHMENT FILM, DICING DIE BONDING FILM, AND SEMICONDUCTOR DEVICE MANUFACTURING METHOD

(71) Applicant: Resonac Corporation, Tokyo (JP)

(72) Inventors: Yuma ARAI, Tokyo (JP); Kanami NAKAMURA, Tokyo (JP)

(73) Assignee: Resonac Corporation, Tokyo (JP)

(21) Appl. No.: 19/478,377

(22) PCT Filed: Sep. 18, 2024
(86) PCT No.: PCT/JP2024/033337

§ 371 Date: Oct. 24, 2025

(30) Foreign Application Priority Data
Sep. 22, 2023 (JP) 2023-158448

(51) Int. Cl. H10W 72/30; H10B 80/00; H10W 72/00; H10W 74/10; H10W 76/15; H10W 90/00; H10W 90/24

(52) U.S. Cl. CPC H10W 72/334; H10W 72/01365; H10W 72/884; H10W 90/24; H10W 90/732; H10W 90/733; H10W 90/754; H10B 80/00; H10W 74/114; H10W 76/15

(57) ABSTRACT

A die attach film for use in bonding a second semiconductor chip to a plurality of spacers disposed on a substrate around a first semiconductor chip such that the second semiconductor chip overlies the first semiconductor chip while bridging between the plurality of spacers. The die attach film exhibits a minimum melt viscosity of 2,000 Pa·s or more and 9,800 Pa·s or less within a range of 90 to 180° C., and the minimum melt viscosity is a value determined by measuring dynamic viscoelasticity of the die attach film over a range including 90 to 180° C. under conditions of a temperature rising rate of 5° C./min and a frequency of 4 Hz.

### TECHNICAL FIELD

The present disclosure relates to a die attach film, a dicing die bonding film, and a method for manufacturing a semiconductor device.

### BACKGROUND ART

In a semiconductor device having a plurality of semiconductor chips, another semiconductor chip may be bonded by an adhesive film (die attach film, DAF) to a plurality of support pieces arranged as spacers around a semiconductor chip on a substrate (see, for example, Patent Literature 1).

### CITATION LIST

### Patent Literature

Patent Literature 1: Japanese Unexamined Patent Publication No. 2023-102570

### SUMMARY OF INVENTION

### Technical Problem

The present disclosure relates to suppressing voids, sink marks, and sagging of a die attach film accompanying thermal curing, with respect to a die attach film used for bonding a second semiconductor chip to a plurality of spacers disposed on a substrate around a first semiconductor chip such that the second semiconductor chip overlies the first semiconductor chip while bridging between the plurality of spacers.

### Solution to Problem

The present disclosure includes the following.

[1]

A die attach film for use in bonding a second semiconductor chip to a plurality of spacers disposed on a substrate around a first semiconductor chip such that the second semiconductor chip overlies the first semiconductor chip while bridging between the plurality of spacers,
wherein the die attach film exhibits a minimum melt viscosity of 2,000 Pa·s or more and 9,800 Pa·s or less within a range of 90 to 180° C., and
wherein the minimum melt viscosity is a value determined by measuring dynamic viscoelasticity of the die attach film over a range including 90 to 180° C. under conditions of a temperature rising rate of 5° C./min and a frequency of 4 Hz.
   [1′]

Application or use of a die attach film for bonding a second semiconductor chip to a plurality of spacers disposed on a substrate around a first semiconductor chip such that the second semiconductor chip overlies the first semiconductor chip while bridging between the plurality of spacers,
wherein the die attach film exhibits a minimum melt viscosity of 2,000 Pa·s or more and 9,800 Pa·s or less within a range of 90 to 180° C., and
wherein the minimum melt viscosity is a value determined by measuring dynamic viscoelasticity of the die attach film over a range including 90 to 180° C. under conditions of a temperature rising rate of 5° C./min and a frequency of 4 Hz.
   [2]

A die attach film for use in bonding a second semiconductor chip to a plurality of spacers disposed on a substrate around a first semiconductor chip such that the second semiconductor chip overlies the first semiconductor chip while bridging between the plurality of spacers,
wherein the die attach film comprises a thermosetting component, an elastomer, and an inorganic filler, and
wherein, based on a mass of the die attach film, a content of the elastomer is 20 mass % or more and 30 mass % or less, and a content of the inorganic filler is 35 mass % or more and 45 mass % or less.
   [2′]

Application or use of a die attach film for bonding a second semiconductor chip to a plurality of spacers disposed on a substrate around a first semiconductor chip such that the second semiconductor chip overlies the first semiconductor chip while bridging between the plurality of spacers,
wherein the die attach film comprises a thermosetting component, an elastomer, and an inorganic filler, and
wherein, based on a mass of the die attach film, a content of the elastomer is 20 mass % or more and 30 mass % or less, and a content of the inorganic filler is 35 mass % or more and 45 mass % or less.
   [3]

The die attach film according to [1] or [2], wherein a wire is connected to the first semiconductor chip, and the die attach film is used to bond the second semiconductor chip such that the second semiconductor chip overlies the first semiconductor chip while bridging between the plurality of spacers and such that the wire is embedded in the die attach film.

[4]

The die attach film according to any one of [1] to [3], for use in bonding the second semiconductor chip to the first semiconductor chip and to the plurality of spacers such that the second semiconductor chip overlies the first semiconductor chip while bridging between the plurality of spacers.

[5]

The die attach film according to any one of [1] to [4], wherein the die attach film exhibits a loss modulus of 200 MPa or less at −2° C. under a condition of a frequency of 10 Hz.

[6]

A dicing die bonding film comprising:
a dicing film; and
the die attach film according to any one of [1] to [5] disposed on the dicing film.
   [7]

A method for manufacturing a semiconductor device, comprising:
preparing an intermediate structure having a substrate, a first semiconductor chip provided on the substrate, and a plurality of spacers disposed on the substrate around the first semiconductor chip;
placing a chip with adhesive on the plurality of spacers of the intermediate structure, the chip with adhesive comprising a second semiconductor chip and a die attach film provided on the second semiconductor chip, such that the die attach film is interposed between the spacers and the second semiconductor chip and such that the second semiconductor chip overlies the first semiconductor chip while bridging between the plurality of spacers, thereby forming a preliminary bonded body comprising the intermediate structure and the chip with adhesive; and
heating the preliminary bonded body to form a bonded body in which the second semiconductor chip is bonded to the plurality of spacers by a cured die attach film,
wherein the die attach film is the die attach film according to any one of [1] to [5].
   [8]

The method according to [7],
wherein a wire is connected to the first semiconductor chip, and
wherein in the bonded body, the second semiconductor chip is bonded to the plurality of spacers by the cured die attach film, and the wire is embedded in the cured die attach film.
   [9]

The method according to [7] or [8], further comprising:
preparing a laminate comprising a dicing die bonding film including a dicing film and the die attach film, and a plurality of the second semiconductor chips formed by dicing a semiconductor wafer, the plurality of the second semiconductor chips being disposed on one die attach film; and
dividing the die attach film by expanding the dicing film while cooling the laminate, thereby forming the chip with adhesive comprising the singulated die attach film.
   [10]

The method according to any one of [7] to [9], wherein, in the bonded body, the second semiconductor chip is bonded by the cured die attach film to the plurality of spacers and to the first semiconductor chip.

### Advantageous Effects of Invention

With respect to a die attach film used for bonding a second semiconductor chip to a plurality of spacers disposed on a substrate around a first semiconductor chip such that the second semiconductor chip overlies the first semiconductor chip while bridging between the plurality of spacers, voids, sink marks, and sagging of the die attach film accompanying thermo-compression bonding and thermal curing can be suppressed.

### BRIEF DESCRIPTION OF DRAWINGS

FIG. 1 is a process diagram showing an example of a method for manufacturing a semiconductor device.

FIG. 2 is a process diagram showing an example of a method for manufacturing a semiconductor device.

FIG. 3 is a process diagram showing an example of a method for manufacturing a semiconductor device.

FIG. 4 is a process diagram showing an example of a method for manufacturing a semiconductor device.

FIG. 5 is a process diagram showing an example of a method for manufacturing a semiconductor device.

FIG. 6 is a process diagram showing an example of a method for preparing a chip with adhesive.

FIG. 7 is a process diagram showing an example of a method for preparing a chip with adhesive.

FIG. 8 is a process diagram showing an example of a method for preparing a chip with adhesive.

FIG. 9 is a plan view showing a preliminary bonded body for evaluating the DA performance of a die attach film.

FIG. 10 is a cross-sectional view showing a preliminary bonded body for evaluating the DA performance of a die attach film.

FIG. 11 is a cross-sectional view showing a preliminary bonded body for evaluating the DA performance of a die attach film.

FIG. 12 is a cross-sectional view showing a preliminary bonded body for evaluating the DA performance of a die attach film.

FIG. 13 is an example of a cross-sectional photograph of a bonded body.

FIG. 14 is an example of a cross-sectional photograph of a bonded body.

FIG. 15 is an example of a cross-sectional photograph of a bonded body.

FIG. 16 is an example of a cross-sectional photograph of a bonded body.

### DESCRIPTION OF EMBODIMENTS

The present invention is not limited to the following examples. In the following examples, unless otherwise specified, the constituent elements (including steps, etc.) are not essential. The size of the constituent elements in each drawing is conceptual, and the relative relationship of the sizes between the constituent elements is not limited to that shown in each drawing. The numerical values and their ranges exemplified below do not limit the present disclosure.

In the present specification, a numerical range indicated using “~” indicates a range including the numerical values described before and after “~” as the minimum and maximum values, respectively. In the numerical ranges described stepwise in the present specification, the upper or lower limit value described in one numerical range may be replaced with the upper or lower limit value of another stepwise described numerical range. In the numerical ranges described in the present specification, the upper or lower limit value of the numerical range may be replaced with a value shown in the examples.

In the present specification, ‘(meth)acrylate’ means acrylate or its corresponding methacrylate. The same applies to other similar expressions such as (meth)acryloyl group, (meth)acrylic copolymer, and the like.

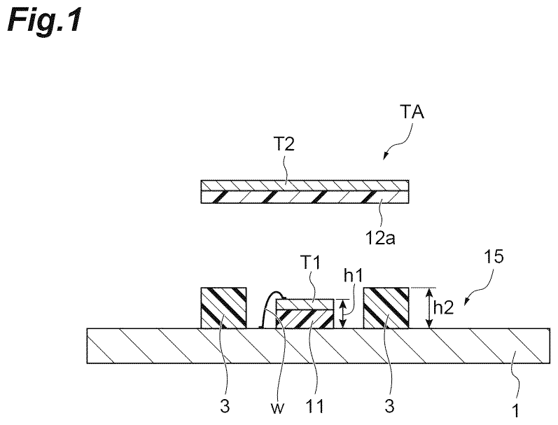

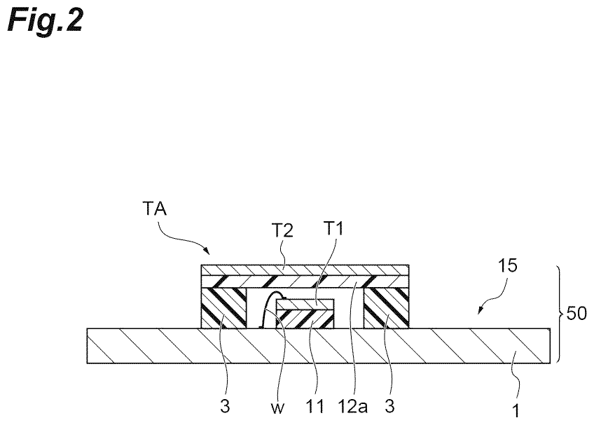

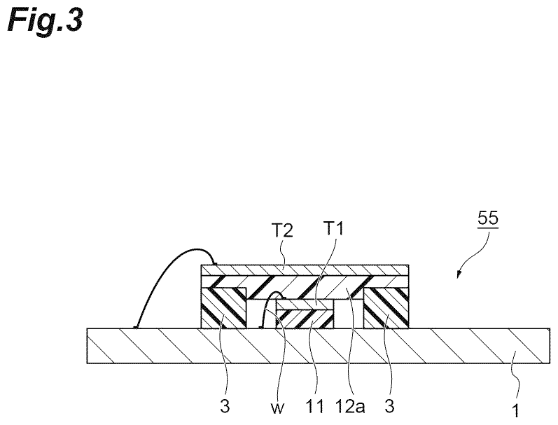

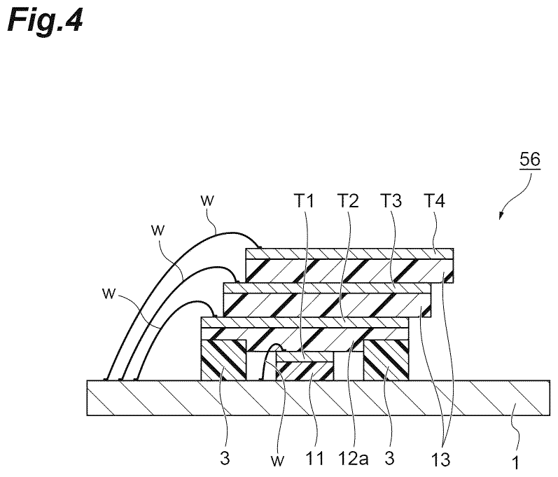

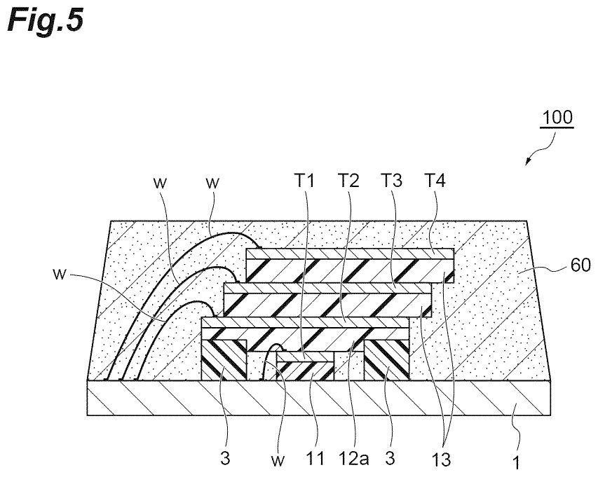

FIGS. 1 to 5 are process diagrams schematically showing an example of a method for manufacturing a semiconductor device. The method shown in FIGS. 1 to 5 includes: preparing an intermediate structure 15 having a substrate 1, a first semiconductor chip T1 provided on the substrate 1, and a plurality of spacers 3 disposed on the substrate 1 around the first semiconductor chip T1 (FIG. 1); placing, on the plurality of spacers 3 of the intermediate structure 15, a chip with adhesive TA including a second semiconductor chip T2 and a die attach film 12a provided on the second semiconductor chip T2, such that the die attach film 12a is interposed between the spacers 3 and the second semiconductor chip T2 and such that the second semiconductor chip T2 overlies the first semiconductor chip T1 while bridging between the plurality of spacers 3, thereby forming a preliminary bonded body 50 having the intermediate structure 15 and the chip with adhesive TA (FIG. 2); heating the preliminary bonded body 50 to form a bonded body 55 in which the second semiconductor chip T2 is bonded to the plurality of spacers 3 by the cured die attach film 12a (FIG. 3); sequentially laminating a third semiconductor chip T3 and a fourth semiconductor chip T4 on a surface of the second semiconductor chip T2 opposite to the substrate 1 via a die attach film 13 which may be the same as or different from the die attach film 12, thereby forming a bonded body 56 having a plurality of semiconductor chips including the first semiconductor chip T1 and the second semiconductor chip T2 (FIG. 4); and forming an encapsulation layer 60 to encapsulate the bonded body 56, thereby obtaining a semiconductor device 100 (FIG. 5).

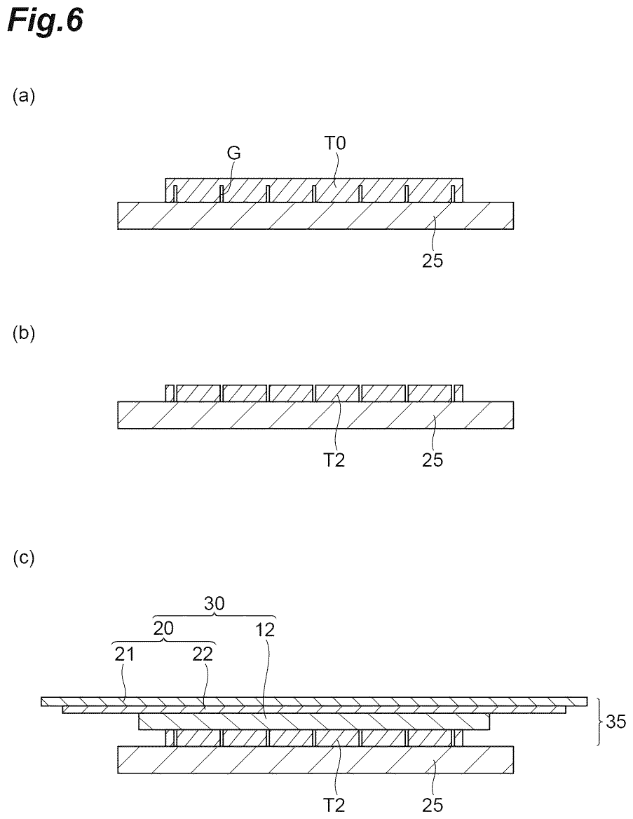

FIGS. 6 to 8 are process diagrams schematically showing an example of a method for preparing a chip with adhesive TA. The method shown in FIGS. 6 to 8 includes: preparing a laminate 35 including a dicing die bonding film 30 having a die attach film 12 and a dicing film 20, and a plurality of second semiconductor chips T2 formed by dicing a semiconductor wafer T0, wherein the plurality of second semiconductor chips T2 are disposed on one die attach film 12; dividing the die attach film 12 by expanding the dicing film 20 while cooling the laminate 35, thereby forming the chip with adhesive TA having the singulated die attach film 12a; and picking up the chip with adhesive TA from the dicing film 20.

The laminate 35 for forming the chip with adhesive TA is formed, for example, by a half-cut dicing method including: forming grooves Gon one surface of a semiconductor wafer T0 by half-cutting the semiconductor wafer T0 as shown in (a) of FIG. 6; dividing the semiconductor wafer T0 into a plurality of second semiconductor chips T2 by grinding the semiconductor wafer T0 from the surface opposite to the grooves G on a backgrind tape 25, as shown in (b) of FIG. 6; and attaching a dicing die bonding film 30 to the surface of the semiconductor chips T2 opposite to the backgrind tape 25, as shown in (c) of FIG. 6. The method for singulating the semiconductor wafer T0 is not limited to the half-cut dicing method, and may be, for example, a stealth dicing method.

The thickness of the second semiconductor chip T2 may be, for example, 1 μm or more and 100 μm or less. The width (maximum width or length of one side) of the second semiconductor chip T2 may be, for example, 20 mm or less. The width (maximum width or length of one side) of the second semiconductor chip T2 may be, for example, 3 mm or more and 15 mm or less, or 5 mm or more and 10 mm or less.

The dicing die bonding film 30 is a laminated film having a dicing film 20 and a die attach film 12. The dicing film 20 may have a base film 21 and an adhesive layer 22 provided on the base film 21. Usually, the die attach film 12 is provided on the adhesive layer 22 side. The dicing film 20 and the adhesive layer 22 have end portions that protrude outward from the end portions of the die attach film 12.

Examples of the base film 21 include resin films such as a polytetrafluoroethylene film, a polyethylene terephthalate film, a polyethylene film, a polypropylene film, a polymethylpentene film, and a polyimide film. The base film 21 may be a resin film whose surface has been treated by primer application, UV treatment, corona discharge treatment, polishing treatment, or etching treatment. The thickness of the base film 21 may be, for example, 20 μm or more and 200 μm or less.

The adhesive layer 22 can be a layer formed of an adhesive commonly used in dicing films. The adhesive constituting the adhesive layer 2 may be an ultraviolet-curable adhesive or a non-ultraviolet-curable adhesive. An ultraviolet-curable adhesive is an adhesive whose adhesiveness decreases upon irradiation with ultraviolet rays. When the dicing film 20 has the adhesive layer 22 formed of an ultraviolet-curable adhesive, for example, the adhesive strength of the adhesive layer 2 may be reduced by ultraviolet irradiation before the chip with adhesive TA is picked up. The thickness of the adhesive layer 2 may be, for example, 1 μm or more and 20 μm or less.

The dicing die bonding film 30 is attached to the plurality of second semiconductor chips T2, with heating if necessary, in an orientation where the die attach film 12 is in contact with the second semiconductor chips T2. The heating temperature for attaching the dicing die bonding film 30 may be, for example, 60° C. or more and 80° C. or less.

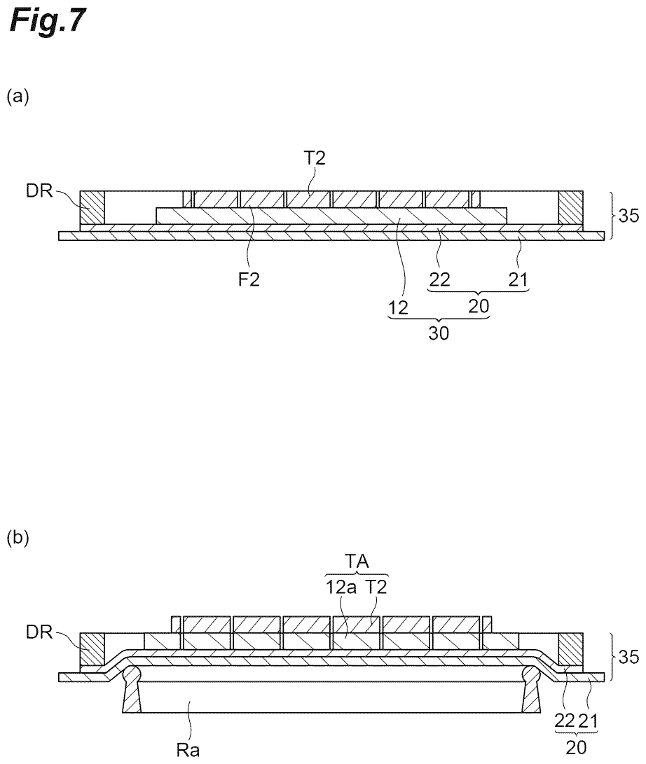

As shown in (a) of FIG. 7, a dicing ring DR is attached to the dicing film 20 of the laminate 35. The dicing ring DR is attached to the end portion of the dicing film 20 (adhesive layer 22) that protrudes from the die attach film 12 so as to surround the second semiconductor chips T2 on the die attach film 12. Before or after the dicing ring DR is attached, the backgrind tape 25 is peeled off from the second semiconductor chips T2.

Subsequently, as shown in (b) of FIG. 7, the dicing film 20 is expanded by cooling expansion in which a region of the dicing film 20 inside the dicing ring DR is pushed up by a ring Ra, while cooling the laminate 35. By expanding the dicing film 20, the die attach film 12 is divided. By the division of the die attach film 12, a chip with adhesive TA having the second semiconductor chip T2 and the singulated die attach film 12 is formed on the dicing film 20. The temperature for cooling the laminate 35 may be, for example, −15° C. or more and 0° C. or less.

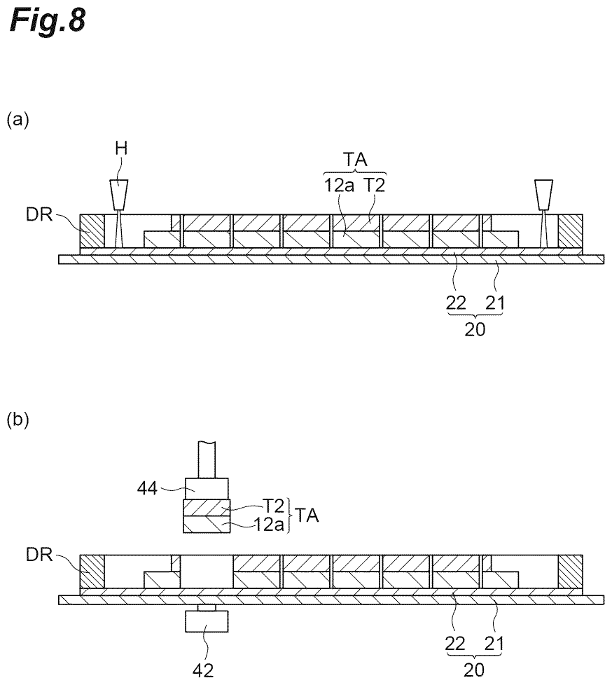

After the ring Ra is lowered, as shown in (a) of FIG. 8, a region between the dicing ring DR of the dicing film 20 and the chip with adhesive TA may be heated by a heater H. Due to the thermal shrinkage of the heated portion of the dicing film 20, the interval (kerf width) between the chips with adhesive TA can be further widened.

After reducing the adhesive strength of the adhesive layer 22 by ultraviolet irradiation or the like, as shown in (b) of FIG. 8, individual chips with adhesive TA pushed up by a push-up jig 42 are picked up by a suction collet 44. The picked-up chip with adhesive TA is used, for example, in the method for manufacturing a semiconductor device shown in FIGS. 1 to 5.

In the case of the method of FIGS. 1 to 5, in addition to the chip with adhesive TA, an intermediate structure 15 having a substrate 1, a first semiconductor chip T1, and spacers 3 is prepared, as shown in FIG. 1.

The first semiconductor chip T1 may be bonded to the substrate 1 by a die attach film 11 which is the same as or different from the die attach film 12. The first semiconductor chip T1 may be connected to a wire w on its surface opposite to the substrate 1. The first semiconductor chip T1 may be a controller chip. The substrate 1 may be an organic substrate or a metal substrate such as a lead frame. The thickness of the substrate 1 may be, for example, 90 μm or more and 300 μm or less. The spacers 3 can be those commonly used in a semiconductor device having a dolmen structure, and may be, for example, a support body including a semiconductor chip.

When the height of the first semiconductor chip T1 from the substrate 1 is h1 and the height of the spacers 3 from the substrate 1 is h2, h1 and h2 may be the same or different. When h1 and h2 are different, voids, sink marks, or sagging of the die attach film 12a accompanying thermal curing tend to occur. When h1 is smaller than h2, sink marks of the die attach film 12a may tend to occur near the end portions of the first semiconductor chip T1. When h1 is larger than h2, a part of the die attach film 12a may tend to sag along the end face of the first semiconductor chip T1. The difference between h1 and h2 may be, for example, 0 μm or more, 1 μm or more, 2 μm or more, 3 μm or more, 4 μm or more, 5 μm or more, 6 μm or more, 7 μm or more, 8 μm or more, or 9 μm or more, and may be 20 μm or less. As will be described later, the die attach film 12a exhibiting a specific minimum melt viscosity under the condition of a frequency of 4 Hz can effectively suppress voids, sink marks, and sagging accompanying thermal curing even when the difference between h1 and h2 is to some extent large. The height h1 of the first semiconductor chip T1 from the substrate 1 may be, for example, 50 μm or more and 100 μm or less. The height h2 of the spacers 3 from the substrate 1 may be, for example, 30 μm or more and 120 μm or less.

The thickness of the first semiconductor chip may be, for example, 1 μm or more and 100 μm or less. The width (maximum width or length of one side) of the first semiconductor chip T1 may be, for example, 20 mm or less. The width (maximum width or length of one side) of the first semiconductor chip T1 may be 3 mm or more and 15 mm or less, or 5 mm or more and 10 mm or less. A wire w may be connected to the first semiconductor chip T1.

As shown in FIG. 2, a second semiconductor chip T2 and a die attach film 12a (chip with adhesive TA) are placed on the intermediate structure 15 such that the die attach film 12 is interposed between the intermediate structure 15 and the second semiconductor chip T2. In the example of FIG. 2, in the preliminary bonded body 50 having the intermediate structure 15 and the chip with adhesive TA, the die attach film 12a is disposed on the spacers 3 of the intermediate structure 15 and is spaced apart from the first semiconductor chip T1. When the height h1 of the first semiconductor chip T1 is the same as or greater than the height h2 of the spacers 3, the first semiconductor chip T1 and the die attach film 12 may be in contact in the preliminary bonded body 50 before being heated.

By heating the preliminary bonded body 50 to thermally cure the die attach film 12a, a bonded body 55 in which the second semiconductor chip T2 is bonded to the intermediate structure 15 (the spacers 3 and the first semiconductor chip T1) is formed, as shown in FIG. 3. The die attach film 12a after thermal curing may, due to flow accompanying the thermal curing, come into contact with the first semiconductor chip T1 and embed a part of the wire w connected to the first semiconductor chip T1. The die attach film 12a after thermal curing may not embed the wire w.

The heating temperature of the preliminary bonded body 50 for forming the bonded body 55 may be constant or may vary. The maximum heating temperature may be 90° C. or more and 180° C. The preliminary bonded body 50 may be heated under pressure, under atmospheric pressure, or under reduced pressure.

Subsequently, as shown in FIG. 4, a wire w connecting the second semiconductor chip T2 and the substrate 1 is provided. Furthermore, a third semiconductor chip T3 and a fourth semiconductor chip T4 may be sequentially laminated on the surface of the second semiconductor chip T2 opposite to the substrate 1, via a die attach film 13 which is the same as or different from the die attach film 12a. Thereby, a bonded body 56 including the first semiconductor chip T1, the second semiconductor chip T2, and one or more added semiconductor chips is formed. A wire w connecting the third semiconductor chip T3 or the fourth semiconductor chip T4 and the substrate 1 may be provided. In the case of the bonded body 56 of FIG. 4, the number of semiconductor chips laminated on the spacers 3 is three, but this number may be four or more, and may be ten or less.

As shown in FIG. 5, by forming an encapsulation layer 60 that encapsulates the bonded body having a plurality of semiconductor chips including the first semiconductor chip T1 and the second semiconductor chip T2, a semiconductor device 100 having a dolmen structure is obtained. The encapsulation layer 60 may fill the space between the first semiconductor chip and the spacers 3. If the die attach film 12a is locally deformed due to sink marks or sagging, the encapsulation layer 60 may enter there, which may cause defects such as cracks in the second semiconductor chip T2. The semiconductor device 100 may be, for example, a 3D NAND flash memory.

Details of an example of a die attach film (particularly, die attach films 12, 12a) that can be used for manufacturing a semiconductor device in the method exemplified above will be described below.

The die attach film may exhibit a minimum melt viscosity of 2,000 Pa·s or more and 9,800 Pa·s or less under a condition of a frequency of 4 Hz in a range of 90 to 180° C. The minimum melt viscosity here means the minimum value of the melt viscosity (shear viscosity or complex viscosity n*) determined by measuring the dynamic viscoelasticity of the die attach film over a range including 90 to 180° C. under conditions of a temperature rising rate of 5° C./min and a frequency of 4 Hz. The melt viscosity of the die attach film usually decreases as the temperature rises, and then increases as the curing reaction proceeds. According to the findings of the present inventors, when the minimum melt viscosity of the die attach film in the dynamic viscoelasticity measurement, particularly under the condition of a frequency of 4 Hz, is 2,000 Pa·s or more and 9,800 Pa·s or less, the occurrence of voids, sink marks, and sagging of the die attach film accompanying thermal curing can be effectively suppressed. From the same viewpoint, the minimum melt viscosity of the die attach film in the dynamic viscoelasticity measurement under the condition of a frequency of 4 Hz may be 2,100 Pa·s or more, 2,200 Pa·s or more, 2,300 Pa·s or more, 2,400 Pa·s or more, 2,500 Pa·s or more, 2,600 Pa·s or more, 2,700 Pa·s or more, 2,800 Pa·s or more, 2,900 Pa·s or more, 3,000 Pa·s or more, 3,100 Pa·s or more, 3,200 Pa·s or more, 3,300 Pa·s or more, 3,400 Pa·s or more, or 3,500 Pa·s or more, and may be 9,500 Pa·s or less, 9,000 Pas or less, 8,000 Pa·s or less, 7,000 Pa·s or less, 6,000 Pa·s or less, 5,000 Pa·s or less, or 4,000 Pa·s or less.

The die attach film may exhibit a loss modulus of 200 MPa or less at −2° C. under a condition of a frequency of 10 Hz. When the loss modulus corresponding to viscosity is low at a low temperature of −2° C., the die attach film is likely to be stably separated when expanded under cooling. From the same viewpoint, the loss modulus of the die attach film at −2° C. under the condition of a frequency of 10 Hz may be 190 MPa or less, or 180 MPa or less, and may be 50 MPa or more.

The loss modulus of the die attach film at −2° C. can be a value determined by measuring the dynamic viscoelasticity of the die attach film over a range including −2° C. under conditions of a temperature rising rate of 3° C./min and a frequency of 10 Hz.

The thickness of the die attach film may be, for example, 10 μm or more, or 20 μm or more, and may be 200 μm or less, 150 μm or less, 120 μm or less, 80 μm or less, or 60 μm or less.

The die attach film may be, for example, a thermosetting adhesive including a thermosetting component, an elastomer, and an inorganic filler.

The thermosetting component may include a thermosetting resin. The thermosetting resin here is a compound that can form a crosslinked structure by a curing reaction including reaction with a curing agent and/or self-polymerization. Examples of the thermosetting resin include epoxy resins, which are compounds having an epoxy group. Examples of the epoxy resin include bisphenol A type epoxy resin, bisphenol F type epoxy resin, bisphenol S type epoxy resin, phenol novolac type epoxy resin, cresol novolac type epoxy resin, bisphenol A novolac type epoxy resin, bisphenol F novolac type epoxy resin, stilbene type epoxy resin, triazine skeleton-containing epoxy resin, fluorene skeleton-containing epoxy resin, triphenolmethane type epoxy resin, biphenyl type epoxy resin, xylylene type epoxy resin, biphenyl aralkyl type epoxy resin, naphthalene type epoxy resin, and diglycidyl ether compounds derived from polyfunctional phenol compounds or polycyclic aromatic compounds (such as anthracene). These may be used singly or in combination of two or more. The epoxy resin may include a combination of an o-cresol novolac type epoxy resin and a bisphenol F type epoxy resin and/or a bisphenol A type epoxy resin.

The thermosetting component may include a curing agent that reacts with the thermosetting resin. The curing agent combined with an epoxy resin as the thermosetting resin can include, for example, a phenol resin. Examples of the phenol resin used as the curing agent include novolac type phenol resin, allylated bisphenol A, allylated bisphenol F, allylated naphthalenediol, phenol aralkyl resin, and naphthol aralkyl resin. These may be used singly or in combination of two or more.

The total content of the thermosetting resin and the curing agent may be, for example, 10 mass % or more, or 15 mass % or more, and may be 80 mass % or less, 70 mass % or less, 60 mass % or less, 50 mass % or less, or 40 mass % or less, based on the mass of the die attach film.

The die attach film may include an imidazole compound. The imidazole compound is a compound having an imidazole ring, and can function, for example, as a curing accelerator that promotes the curing reaction between an epoxy resin and its curing agent (such as a phenol resin). The imidazole compound may be, for example, at least one selected from the group consisting of 1-cyanoethyl-2-phenylimidazole, 2-phenylimidazole, and 1-benzyl-2-methylimidazole. The content of the imidazole compound may be 0.03 mass % or more, and may be 1.0 mass % or less, 0.90 mass % or less, 0.80 mass % or less, 0.70 mass % or less, 0.60 mass % or less, 0.5 mass % or less, 0.40 mass % or less, 0.30 mass % or less, 0.20 mass % or less, 0.10 mass % or less, or 0.09 mass % or less, based on the mass of the die attach film.

The elastomer may be, for example, an acrylic rubber. The acrylic rubber is an elastomer including monomer units derived from a (meth)acrylic acid ester. The content of the constituent units derived from a (meth)acrylic acid ester in the acrylic rubber may be, for example, 70 mass % or more, 80 mass % or more, or 90 mass % or more, based on the total amount of the acrylic rubber. The acrylic rubber may include monomer units derived from a (meth)acrylic acid ester having a crosslinkable functional group such as an epoxy group, an alcoholic or phenolic hydroxyl group, and a carboxyl group. The acrylic resin may be a copolymer including a (meth)acrylic acid ester and acrylonitrile as monomer units.

The glass transition temperature (Tg) of the elastomer (for example, acrylic resin) may be −50° C. or higher, −30° C. or higher, 0° C. or higher, or 3° C. or higher, and may be 50° C. or lower, 45° C. or lower, 40° C. or lower, 35° C. or lower, 30° C. or lower, or 25° C. or lower. The glass transition temperature (Tg) means a value measured using a DSC (Differential Scanning calorimeter) (for example, “Thermo Plus 2” manufactured by Rigaku Corporation). The Tg of the elastomer can be adjusted to a desired range by adjusting the type and content of the constituent units constituting the elastomer (in the case of an acrylic resin, constituent units derived from a (meth)acrylic acid ester).

The weight-average molecular weight (Mw) of the elastomer (for example, acrylic rubber) may be 100,000 or more, 200,000 or more, or 300,000 or more, and may be 3,000,000 or less, 2,000,000 or less, or 1,000,000 or less. When the Mw of the elastomer is in such a range, the viscoelasticity of the die attach film 12 tends to be appropriately controlled. Mw means a value converted using a calibration curve with standard polystyrene, measured by gel permeation chromatography (GPC).

Examples of commercially available acrylic rubbers include SG-70L, SG-708-6, WS-023 EK30, SG-280 EK23, SG-P3 (all manufactured by Nagase ChemteX Corporation), and H-CT-865 (manufactured by Resonac Corporation).

When the content of the elastomer is large, the minimum melt viscosity of the die attach film tends to be large. When the content of the elastomer is small, the loss modulus of the die attach film at −2° C. tends to be small. From these viewpoints, the content of the elastomer may be 5 mass % or more, 10 mass % or more, 15 mass % or more, or 20 mass % or more, and may be 50 mass % or less, 45 mass % or less, 40 mass % or less, 35 mass % or less, or 30 mass % or less, based on the mass of the die attach film 12.

The inorganic filler may be particles including at least one inorganic material selected from aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whiskers, boron nitride, and silica. The inorganic filler may include a silica filler.

The average particle size of the inorganic filler may be 0.01 μm or more, or 0.03 μm or more, and may be 1.5 μm or less, 1.0 μm or less, 0.8 μm or less, 0.08 μm or less, or 0.06 μm or less. Two or more types of inorganic fillers with different average particle sizes may be combined. The average particle size means a value determined by conversion from the BET specific surface area.

When the content of the inorganic filler is large, the minimum melt viscosity of the die attach film tends to be large, and the loss modulus of the die attach film at −2° C. tends to decrease. The content of the inorganic filler may be 10 mass % or more, 15 mass % or more, 20 mass % or more, 25 mass % or more, 30 mass % or more, or 35 mass % or more, and may be 60 mass % or less, 55 mass % or less, 50 mass % or less, or 45 mass % or less, based on the mass of the die attach film.

For example, when the content of the elastomer is 20 mass % or more and 30 mass % or less and the content of the inorganic filler is 35 mass % or more and 45 mass % or less, based on the mass of the die attach film, both a minimum melt viscosity of 2,000 Pa·s or more and 9,800 Pa·s or less under a condition of a frequency of 4 Hz in a range of 90 to 180° C., and a loss modulus of 200 MPa or less at −2° C. are likely to be satisfied.

The die attach film may further include a coupling agent. The coupling agent may be a silane coupling agent. Examples of the silane coupling agent include Y-ureidopropyltriethoxysilane, γ-mercaptopropyltrimethoxysilane, 3-phenylaminopropyltrimethoxysilane, and 3-(2-aminoethyl)aminopropyltrimethoxysilane. These may be used singly or in combination of two or more. The die attach film may further include other components such as a pigment, an ion scavenger, and an antioxidant.

### EXAMPLES

The present invention is not limited to the following examples.

### 1. Preparation of Die Attach Film

An adhesive varnish containing the following materials in the amounts (unit: parts by mass) shown in Table 1 was prepared. The contents of the elastomer and inorganic filler shown in Table 1 are the amounts of the solid content (acrylic rubber or silica filler) excluding the solvent.

### (A) Epoxy Resin

N-500P-10 (trade name, manufactured by DIC Corporation, o-cresol novolac type epoxy resin, epoxy equivalent: 203 g/eq)
EXA-830CRP (trade name, manufactured by DIC Corporation, bisphenol F type epoxy resin, epoxy equivalent: 158-168 g/eq)

### (B) Curing Agent (Phenol Resin)

MEH-7800M (trade name, manufactured by Meiwa Chemical Co., Ltd., phenol novolac type phenol resin, hydroxyl equivalent: 175 g/eq, softening point: 61-90° C.)

### (C) Inorganic Filler

Silica filler 1 (silica filler dispersion, average particle size: 0.50 μm)
Silica filler 2 (silica filler dispersion, average particle size: 0.30 μm)
Silica filler 3 (silica filler dispersion, average particle size: 0.016 μm)

### (D) Elastomer

SG-P3 (trade name, manufactured by Nagase ChemteX Corporation, acrylic rubber, weight-average molecular weight: 800,000, Tg: 12° C., cyclohexanone solution)

### (E) Coupling Agent

A-189 (trade name, manufactured by Nippon Unicar Company Limited, γ-mercaptopropyltrimethoxysilane)
A-1160 (trade name, manufactured by Nippon Unicar Company Limited, 3-ureidopropyltriethoxysilane)

### (F) Curing Accelerator

2PZ-CN (trade name, manufactured by Shikoku Chemicals Corporation, 1-cyanoethyl-2-phenylimidazole)

Each prepared adhesive varnish was filtered through a 500-mesh filter. Each filtered adhesive varnish was vacuum-defoamed. The adhesive varnish after vacuum defoaming was applied onto a release-treated polyethylene terephthalate (PET) film (support film). The coating film was dried by a two-stage heating at 90° C. for 5 minutes and then at 130° C. for 5 minutes to form a B-stage die attach film (thickness: 20 μm) on the support film.

### 2. Evaluation

### (1) Minimum Melt Viscosity

Eight film pieces of a predetermined size cut out from the die attach film were prepared. They were laminated using a rubber roller on a hot plate at 70° C. to prepare a laminate with a thickness of 400 μm. This laminate was punched out with a 99 mm punch to produce a disk-shaped sample having a circular surface with a diameter of about 9 mm. The sample was mounted on a measurement jig of a rotational viscoelasticity measuring device (trade name: ARES-RDA, manufactured by TA Instruments Japan Inc.). At this point, the gap of the measurement jig was adjusted so that the load applied to the sample was 10 to 15 g. Subsequently, the dynamic viscoelasticity of the sample was measured under the following conditions. From the measurement results, the minimum melt viscosity (minimum value of shear viscosity) in the range of 90 to 180° C. was read.

### Measurement Conditions:

Disk plate: Aluminum, circular (8 mmo)
Measurement frequency: 4 Hz
Temperature rising rate: 5° C./min
Strain: 5%
Measurement temperature: 35-180° C.
Initial load: 100 g

### (2) Loss Modulus at −2° C.

A plurality of die attach films were laminated using a rubber roller on a hot plate at 70° C. to form a laminate with a thickness of 120 μm. A rectangular parallelepiped sample for measurement having a surface of 4 mm width×25 mm length was cut out from this laminate. The sample was mounted on a dynamic viscoelasticity measuring device (Rheogel-E4000, manufactured by UBM Co., Ltd.), and the dynamic viscoelasticity of the sample was measured under the following conditions. From the measurement results, the loss modulus at −2° C. was read and taken as the loss modulus of the die attach film at 150° C.

### Measurement Conditions:

Measurement mode: Tensile
Chuck-to-chuck distance: 20 mm
Temperature rising rate: 3° C./min
Frequency: 10 Hz
Load: Automatic static load
Measurement temperature:-10 to 30° ° C.

Table 1 shows the measurement results of the dynamic viscoelasticity of each die attach film. For Comparative Example 1, the minimum melt viscosity at a frequency of 1 Hz is also shown in the table.

TABLE 1

| | | Comp. | | | | Comp. |
|---|---|---|---|---|---|---|
| | | Ex. 1 | Ex. 1 | Ex. 2 | Ex. 3 | Ex. 2 |
| Epoxy resin | N-500P-10 | 10.43 | 7.52 | 14.13 | 11.39 | 12.6 |
| | EXA- | 13.02 | 9.39 | 5.43 | 7.95 | — |
| | 830CRP | | | | | |
| Curing agent | MEH- | 19.14 | 13.77 | 14.86 | 15.18 | 11.5 |
| | 7800M | | | | | |
| Inorganic filler | Silica filler 1 | 39.05 | 44.00 | — | — | — |
| | Silica filler 2 | — | — | 42.49 | 40.43 | — |
| | Silica filler 3 | — | — | — | — | 7.9 |
| Elastomer | SG-P3 | 18.03 | 25.00 | 22.76 | 24.73 | 66.4 |
| Silane coupling agent | A-189 | 0.09 | 0.09 | 0.09 | 0.09 | 0.4 |
| | A-1160 | 0.18 | 0.18 | 0.18 | 0.18 | 1.2 |
| Imidazole compound | 2PZ-CN | 0.12 | 0.04 | 0.05 | 0.05 | 0.03 |

| | | | | | |
|---|---|---|---|---|---|
| Minimum melt viscosity | 1460 | 2490 | 3530 | 3080 | 9850 |
| [Pa · s / 4 Hz] (Temperature [° C.]) | (116) | (138) | (131) | (134) | (152.7) |
| Loss modulus @−2° C. [MPa / 10 Hz] | 164 | 211 | 173 | 186 | 93 |
| Minimum melt viscosity | 3920 | — | — | — | — |
| [Pa · s / 1 Hz] | | | | | |

### (3) DA Performance

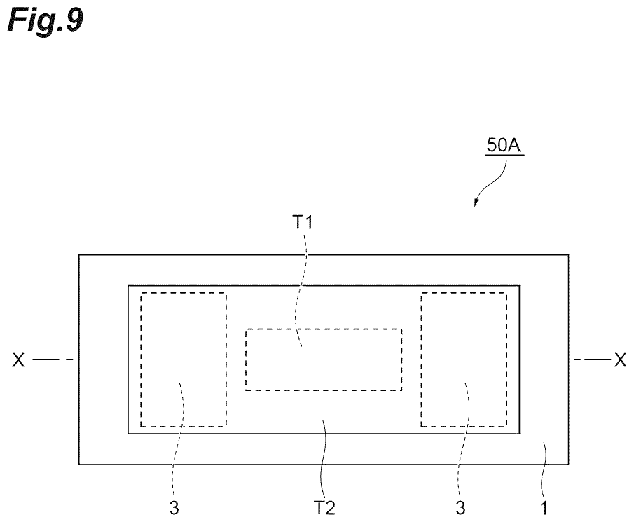

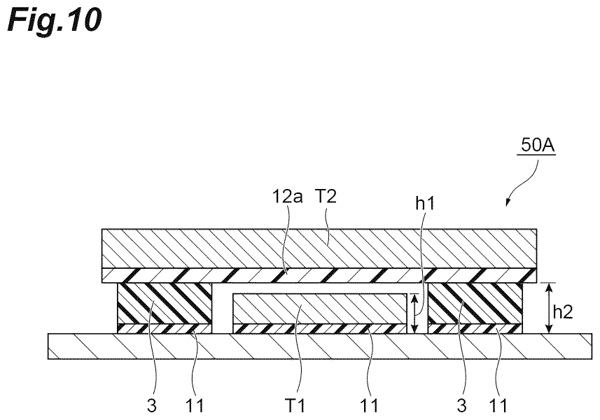

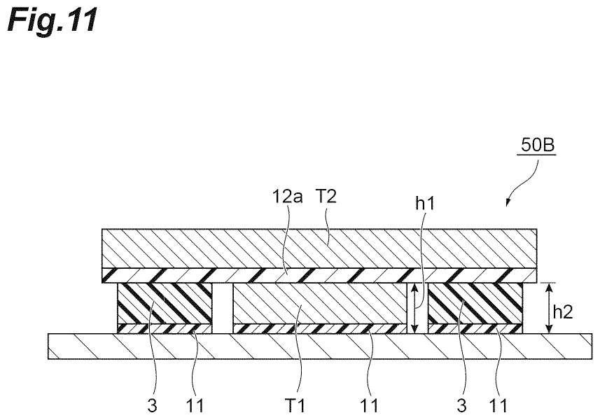

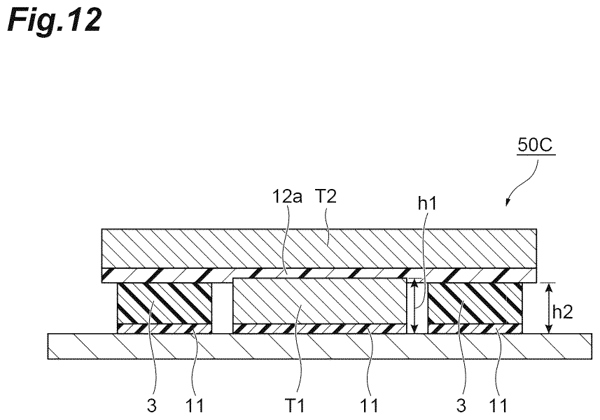

FIGS. 9, 10, 11, and 12 show a preliminary bonded body for evaluating the DA performance of the die attach film. FIG. 9 is a plan view of a preliminary bonded body 50A, and FIG. 10 is a cross-sectional view taken along the line X-X of FIG. 9. The preliminary bonded body 50A has a substrate 1, a first semiconductor chip T1 having a size of 1.6 mm×4.5 mm, two spacers 3 having a size of 3.6 mm×2.5 mm, and a second semiconductor chip T2 having a size of 4.0 mm×12 mm. On the substrate 1, the two spacers 3 are disposed on both sides of the first semiconductor chip T1. The first semiconductor chip T1 and the spacers 3 are bonded to the substrate 1 via a die attach film 11. h1 is the height from the substrate 1 including the die attach film 11 and the first semiconductor chip T1, and h2 is the height from the substrate 1 including the die attach film 11 and the spacers 3. In the case of the preliminary bonded body 50A of FIG. 10, h1 is 65 μm and h2 is 75 μm, so h1<h2. The preliminary bonded body 50B of FIG. 11 differs from the preliminary bonded body 50A in that h1 is 75 μm, so h1=h2. The preliminary bonded body 50C of FIG. 12 differs from the preliminary bonded body 50A in that h1 is 85 μm, so h1>h2.

A chip with adhesive having a second semiconductor chip T2 and a die attach film attached thereto was prepared. As the die attach film, the die attach film of Comparative Example 1 or Example 2 prepared in “1. Preparation of Die Attach Film” was used. The prepared chip with adhesive was laminated on the spacers 3 so as to overlie the first semiconductor chip T1, thereby forming preliminary bonded bodies 50A, 50B, and 50C. The preliminary bonded bodies 50A, 50B, and 50C were pressure-bonded by a hot press at 120° C. for 1.5 seconds. The pressure of the hot press was set to 45 N for the preliminary bonded body 50A and 30 N for the preliminary bonded bodies 50B and 50C. By this thermo-compression bonding, the die attach film was cured to form a bonded body in which the second semiconductor chip T2 was bonded to the spacers 3 and the first semiconductor chip T1.

The interface between the cured die attach film and the first semiconductor chip T1 in the formed bonded body was observed using an ultrasonic digital imaging diagnostic apparatus (trade name: IS-350, manufactured by Insight K.K.) at 75 MHz in reflection mode, and the area ratio of voids at a predetermined interface was determined. When the area ratio was 5% or more, it was judged as having voids.

The formed bonded body was cut in half, and the shape of the cured die attach film in the cross-section was observed with an optical microscope. In the vicinity of the end portion of the first semiconductor chip T1, when the maximum thickness t1 of the portion of the die attach film that sagged below the main surface of the first semiconductor chip T1 on the die attach film side was 26 μm or more, it was judged as having sagging. When a portion where the thickness t2 of the die attach film decreased to a minimum of 10 μm or less due to a sink mark at the end portion of the first semiconductor chip T1 was observed, it was judged as having a sink mark.

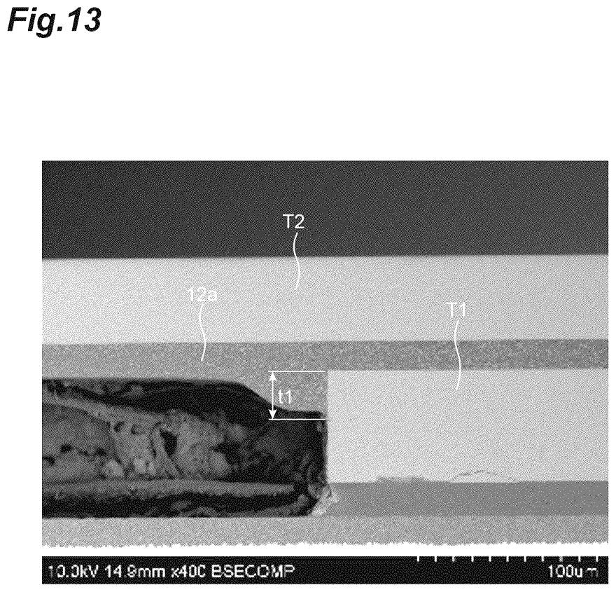

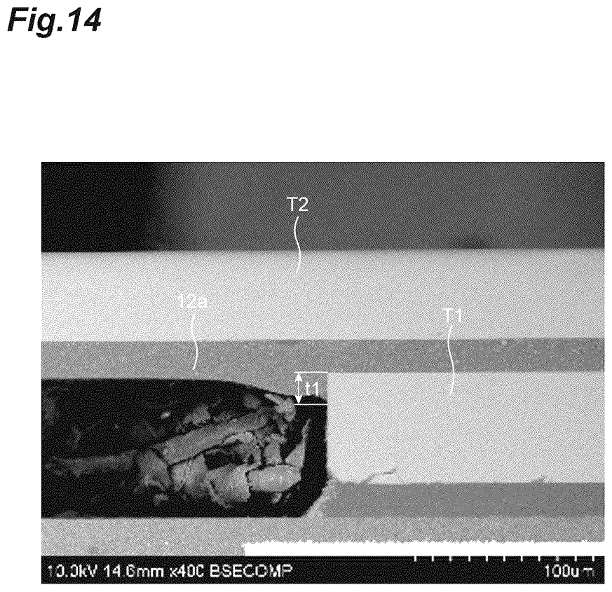

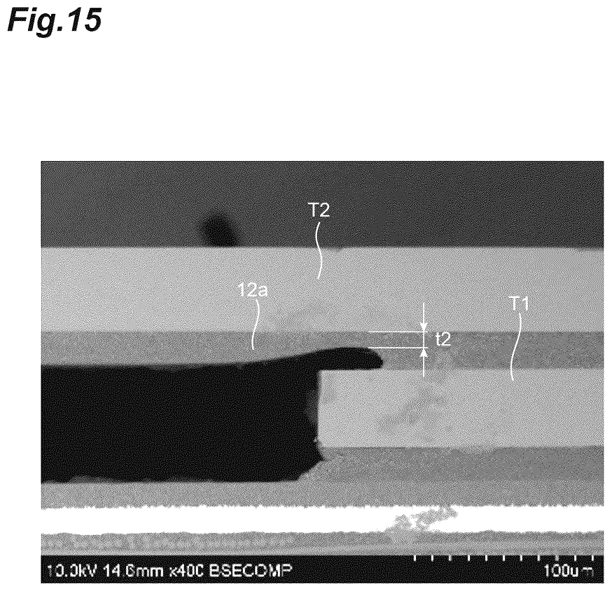

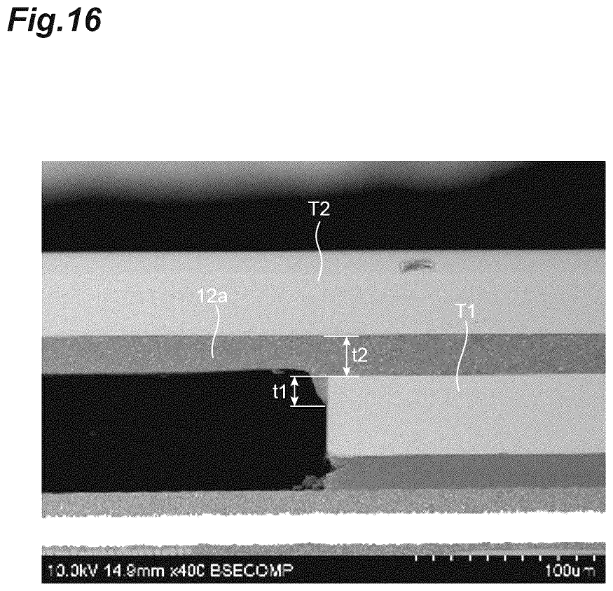

FIG. 13 is a cross-sectional photograph of a bonded body formed from the preliminary bonded body 50C of Comparative Example 1. The occurrence of sagging with a maximum thickness t1 of 26 μm was observed. FIG. 14 is a cross-sectional photograph of a bonded body formed from the preliminary bonded body 50C of Example 2. The maximum thickness t1 remained 20 μm or less. FIG. 15 is a cross-sectional photograph of a bonded body formed from the preliminary bonded body 50A in the case of Comparative Example 1. The occurrence of a sink mark where the thickness t2 became 10 μm or less was observed. FIG. 16 is a cross-sectional photograph of a bonded body formed from the preliminary bonded body 50A of Example 2. Neither sagging with a thickness t1 of 26 μm or more nor a sink mark with a thickness t2 of 10 μm or less was observed. Table 2 shows the observation results of voids, sagging, and sink marks.

TABLE 2

| | | | Comp. | | Comp. |
|---|---|---|---|---|---|
| | | | Ex. 1 | Ex. 2 | Ex. 2 |
| Minimum melt viscosity [Pa · s/4 Hz] | | | 1460 | 3530 | 9850 |
| Loss modulus @−2° C. [MPa/10 Hz] | | | 164 | 173 | 93 |
| DA | Preliminary | Void | None | None | Present |
| property | bonded | Sagging | None | None | None |
| | body 50A | Sink mark | Present | None | None |
| | h1 < h2 | | | | |
| | Preliminary | Void | None | None | Present |
| | bonded | Sagging | None | None | None |
| | body 50B | Sink mark | None | None | None |
| | h1 = h2 | | | | |
| | Preliminary | Void | None | None | Present |
| | bonded | Sagging | Present | None | None |
| | body 50C | Sink mark | None | None | None |
| | h1 > h2 | | | | |

### (2) Cool-Separability

Each die attach film prepared in “1. Preparation of Die Attach Film” and a dicing tape having an adhesive layer were laminated to prepare a dicing die bonding film. In the dicing die bonding film, the adhesive layer protruded outward from the end portion of the die attach film. On one surface of a silicon wafer, grooves corresponding to silicon chips having a size of 4×12 mm were formed by half-cut dicing. A backgrind tape was attached to the surface of the silicon wafer on which the grooves were formed. The silicon wafer was singulated by grinding the surface of the silicon wafer on which the grooves were formed from the side opposite to the backgrind tape using a grinder-polisher apparatus until the thickness of the silicon wafer became 50 μm. The die attach film of the dicing die bonding film was attached to the surface of the silicon chips formed by singulation opposite to the backgrind tape while heating to 70° C. The portion of the adhesive layer protruding from the die attach film was attached to a dicing ring, and then the backgrind tape was peeled off from the silicon chips. Next, using a die separator (DDS2300, manufactured by DISCO Corporation), the dicing film of the dicing die bonding film was expanded by cooling expansion under the following cooling expansion conditions, thereby dividing the die attach film. Thereafter, the dicing film was shrunk by heating (heat shrink) under the following heating conditions.

### (Cooling Expand Conditions)

Cooling temperature: −2° C.
Cooling time: 100 seconds
Push-up amount: 21 mm
Push-up speed: 300 mm/see
Holding time after push-up: 3 seconds

### (Heating Conditions)

Heater temperature: 250° C.
Heater rotation speed: 4°/see
Push-up amount: 12 mm
Tape cooling waiting time: 3 seconds

After the shrinkage of the dicing film, the adhesive layer was irradiated with ultraviolet rays under the following conditions, thereby reducing the adhesive strength of the adhesive layer. (Ultraviolet irradiation conditions)
Ultraviolet illuminance: 80 mW/cm²
Ultraviolet irradiation dose: 130 mJ/cm²

After the above cool-separability test, light was irradiated onto the entirety of the plurality of formed chips with adhesive. A case where the die attach film was appropriately divided between adjacent chips with adhesive and light passed through without being blocked by the die attach film was judged as “A”, and a case where a region where light did not pass through because it was blocked by an inappropriately divided die attach film was observed was judged as “B”.

TABLE 3

| | Comp. | | | | Comp. |
|---|---|---|---|---|---|
| | Ex. 1 | Ex. 1 | Ex. 2 | Ex. 3 | Ex. 2 |
| Minimum melt viscosity | 1460 | 2490 | 3530 | 3080 | 9850 |
| [Pa · s @4 Hz] | | | | | |
| Loss modulus @−2° C. | 164 | 211 | 173 | 186 | 93 |
| [MPa] | | | | | |
| Cool-separability | A | B | A | A | B |

The evaluation results of cool-separability are shown in Table 3. From the comparison between Example 1 and Examples 2 and 3, it was confirmed that when the loss modulus at −2° C. is 200 MPa or less, good cool-separability is exhibited. Furthermore, from the evaluation result of cool-separability of Comparative Example 2, it was confirmed that a moderately low minimum melt viscosity also contributes to the improvement of cool-separability.

Reference Signs List

1 . . . substrate, 3 . . . spacer, 11, 12, 13 . . . die attach film, 12a . . .
singulated die attach film, 15 . . . intermediate structure, 20 . . . dicing film,
21 . . . base film, 22 . . . adhesive layer, 30 . . . dicing die bonding film, 35 . . .
laminate, 42 . . . push-up jig, 44 . . . suction collet, 50, 50A, 50B, 50C . . .
preliminary bonded body, 55, 56 . . . bonded body, 60 . . . encapsulation layer,
100 . . . semiconductor device, T0 . . . semiconductor wafer, T1 . . . first
semiconductor chip, T2 . . . second semiconductor chip, TA . . . chip with
adhesive, DR . . . dicing ring, G . . . groove, H . . . heater, Ra . . . ring, w . . . wire.

1. A die attach film configured to bond a second semiconductor chip to a plurality of spacers disposed on a substrate around a first semiconductor chip such that the second semiconductor chip overlies the first semiconductor chip while bridging between the plurality of spacers,
wherein the die attach film exhibits a minimum melt viscosity of 2,000 Pa·s or more and 9,800 Pa·s or less within a range of 90 to 180° C., and
wherein the minimum melt viscosity is a value determined by measuring dynamic viscoelasticity of the die attach film over a range including 90 to 180° C. under conditions of a temperature rising rate of 5° C./min and a frequency of 4 Hz.

2. A die attach film configured to bond a second semiconductor chip to a plurality of spacers disposed on a substrate around a first semiconductor chip such that the second semiconductor chip overlies the first semiconductor chip while bridging between the plurality of spacers,
wherein the die attach film comprises a thermosetting component, an elastomer, and an inorganic filler, and
wherein, based on a mass of the die attach film, a content of the elastomer is 20 mass % or more and 30 mass % or less, and a content of the inorganic filler is 35 mass % or more and 45 mass % or less.

3. The die attach film according to claim 1, wherein a wire is connected to the first semiconductor chip, and the die attach film is configured to bond the second semiconductor chip such that the second semiconductor chip overlies the first semiconductor chip while bridging between the plurality of spacers and such that the wire is embedded in the die attach film.

4. The die attach film according to claim 1, for configured to bond the second semiconductor chip to the first semiconductor chip and to the plurality of spacers such that the second semiconductor chip overlies the first semiconductor chip while bridging between the plurality of spacers.

5. The die attach film according to claim 1, wherein the die attach film exhibits a loss modulus of 200 MPa or less at −2° C. under a condition of a frequency of 10 Hz.

6. A dicing die bonding film comprising:
a dicing film; and
the die attach film according to claim 1 disposed on the dicing film.

7. A method for manufacturing a semiconductor device, comprising:
preparing an intermediate structure comprising a substrate, a first semiconductor chip provided on the substrate, and a plurality of spacers disposed on the substrate around the first semiconductor chip;
placing a chip with adhesive on the plurality of spacers of the intermediate structure, the chip with adhesive comprising a second semiconductor chip and a die attach film provided on the second semiconductor chip, such that the die attach film is interposed between the spacers and the second semiconductor chip and such that the second semiconductor chip overlies the first semiconductor chip while bridging between the plurality of spacers, thereby forming a preliminary bonded body comprising the intermediate structure and the chip with adhesive; and
heating the preliminary bonded body to form a bonded body in which the second semiconductor chip is bonded to the plurality of spacers by a cured die attach film,
wherein the die attach film is the die attach film according to claim 1.

8. The method according to claim 7,
wherein a wire is connected to the first semiconductor chip, and
wherein in the bonded body, the second semiconductor chip is bonded to the plurality of spacers by the cured die attach film, and the wire is embedded in the cured die attach film.

9. The method according to claim 7, further comprising:
preparing a laminate comprising a dicing die bonding film including a dicing film and the die attach film, and a plurality of the second semiconductor chips formed by dicing a semiconductor wafer, the plurality of the second semiconductor chips being disposed on one die attach film; and
dividing the die attach film by expanding the dicing film while cooling the laminate, thereby forming the chip with adhesive comprising the singulated die attach film.

10. The method according to claim 7, wherein, in the bonded body, the second semiconductor chip is bonded by the cured die attach film to the plurality of spacers and to the first semiconductor chip.
